(19) United States
(12) Patent Application Publication
(10) Pub. No.: US 2025/0155663 A1
(43) Pub. Date: May 15, 2025

(54) HOLOGRAPHIC OPTICAL ELEMENT AND TEMPERATURE STABILIZATION

(71) Applicant: Carl Zeiss Jena GmbH, Jena (DE)

(72) Inventors: Mirko RIETHMÜLLER, Jena (DE); Viktor SCHÜTZ, Jena (DE); Christian SCHINDLER, Jena (DE)

(73) Assignee: Carl Zeiss Jena GmbH, Jena (DE)

(21) Appl. No.: 18/728,646

(22) PCT Filed: Jan. 13, 2023
(86) PCT No.: PCT/EP2023/050729

§ 371 Date: Jul. 12, 2024

(30) Foreign Application Priority Data
Jan. 14, 2022 (DE) 10 2022 100 805.3

(51) Int. Cl. G02B 7/00; G02B 5/32

(52) U.S. Cl. CPC G02B 7/008; G02B 5/32

(57) ABSTRACT

Different examples relate to techniques in order to actively or passively stabilize the temperature of a holographic optical element. To this end, heat-conducting elements, e.g. silver nanowires or carbon nanotubes, are provided.

### RELATED APPLICATIONS

The present application is a National Phase patent application of PCT Appl. No. PCT/EP2023/050729, filed on Jan. 13, 2023, which claims priority to German Patent Appl. No. DE102022100805.3, filed on Jan. 14, 2022, and is hereby fully incorporated herein by reference.

### FIELD OF THE INVENTION

Various examples relate to a system comprising a substrate and at least one layer which is applied on the substrate and comprises a holographic optical element. Moreover, a heat-conducting element is provided in order to enable temperature stabilization of the holographic optical element.

### BACKGROUND OF THE INVENTION

Holographic optical elements are typically implemented in one or more thin layers applied on a substrate. The substrate thus serves as a carrier. The substrate and/or the one or more layers can be embodied as films. The one or more layers can consist of a photopolymer. A plurality of such layers, each embodying a holographic optical element (also abbreviated to HOE), can be stacked. If a holographic optical element is illuminated with light in a predetermined wavelength range, a hologram is reconstructed.

It has been observed that the optical efficiency of the reconstruction of the hologram varies in practical applications. Sometimes the hologram is reconstructed less efficiently than in other situations. By way of example, the brightness of the hologram may then vary. Sometimes the hologram may not be perceptible particularly well. Moreover, laterally varying brightnesses of the hologram have been observed, that is to say at different positions the hologram has different brightnesses and such a laterally varying brightness may also vary depending on the environmental situation. That means that a different efficiency is observed during the reconstruction, depending on the partial region of the hologram.

Document DE 10 2009 008 658 A1 discloses an element, and in particular a transparent element. The transparent element is characterized in that a first region at least partly constitutes a projection screen for visualizing projected light images, and there is a second region equipped with at least one illuminant. In that case, the transparent element has only one structured conductive layer for the electrical supply of the illuminants. In that case, the structured conductive layer can have conductor track structures, for example. Furthermore, the transparent element does not have a heat-conducting element included in a layer, and in particular does not have nanowires or a network of nanowires. Furthermore, the document DE 10 2009 008 658 A1, in the context of holographic optical elements, arranges illuminants laterally and not in the same region as the holographic optical elements (cf. FIG. 2f).

Document DE 10 2008 012 844 A1 discloses a lighting device. The lighting device has at least one integral, substantially planar carrier medium which is embodied from a solid substance and has two opposing main sides. Furthermore, the lighting device has at least two electrical lines and at least one semiconductor element designed to emit electromagnetic radiation at least partly in a wavelength range in which the carrier medium is substantially transparent. In that case, the semiconductor element is embedded in the carrier medium in such a way that it emits substantially along at least one main extension direction of the carrier medium. The carrier medium can at least partly comprise a thermally conductive material or the lighting device can have at least one layer which functions as a heat sink. In that case, neither the carrier medium nor the lighting device has nanowires or a network of nanowires.

Document DE 198 43 902 A1 discloses an image information display system and a hologram display device. The system contains a sensor that detects a person entering the viewing angle of the hologram screen. A controller adjusts the projector depending on the sensor signals so that the projector can project image information onto the screen. The system is installed in an exhibition area. The hologram screen is of the transmission type. The transparent carrier to which the screen is secured is a glass window of the exhibition area. An exhibition item is situated behind the screen. The hologram display system or components thereof can be arranged for alleviating a thermal effect. However, the hologram display device does not have a heat-conducting element included in a layer, and in particular does not have nanowires or a network of nanowires.

Document WO 2017/108704 A1 discloses a device and a method for the industrial production of volume reflection holograms with substrate-guided reconstruction beams. The volume reflection hologram produced by means of the device and the method does not have heat-conducting elements.

Document US 2012/0099170 A1 discloses a see-through display comprising a light source for emitting light, an optical projection system for projecting the light emitted by the light source, and a volume hologram for deflecting the light projected by the optical projection system. The volume hologram has a linear expansion coefficient of α (/° C.) and interference fringes recorded with recording light having a wavelength of Λ (nm). The wavelength of the light emitted by the light source has a temperature dependency of K (nm/° C.), and the wave-length Λ (nm) and the temperature dependency K (nm/° C.) satisfy the relationship 0≤K/Λ≤2α.The volume hologram can be arranged between a glass layer and an intermediate layer that absorbs infrared or ultraviolet radiation, in order to avoid thermal expansion of the volume hologram. None of the layers of the volume hologram has a heat-conducting element, and in particular does not have nanotubes or a network of nanowires.

### SUMMARY OF THE INVENTION

Therefore, there is a need for improved techniques in connection with holographic optical elements and the reconstruction of holograms. In particular, there is a need for techniques which enable an efficient reconstruction of holograms even in practical applications under varying ambient conditions.

A system comprises at least one substrate. Moreover, the system comprises at least one first layer and at least one second layer. The at least one first layer is applied on the at least one substrate. The at least one first layer comprises a holographic optical element. The at least second layer is also applied on the at least one substrate. Each of the at least one second layer comprises at least one respective heat-conducting element.

Upon illumination by light with suitable parameters (for example illumination angle and wavelength), the holographic optical elements of the at least one first layer can reconstruct one or more holograms.

For this purpose, each holographic optical element can have a grating structure. The holographic optical element can be embodied with a volume geometry or with a surface geometry; a variety of techniques are previously known here, in principle, which influence the thickness of the grating structure. Diffraction and interference effects can be used for the reconstruction of the hologram.

The at least one heat-conducting element can have a thermal conductivity which is greater than the thermal conductivity of the at least one first layer. That means that the heat-conducting element can transfer heat comparatively well.

The at least one heat-conducting element can operate as a heat source or heat sink. The holographic optical elements can be heated or cooled. The at least one heat-conducting element can thus provide temperature stabilization for the one or more holographic optical elements of the at least one first layer.

The system can have a temperature-regulating layer configured to provide temperature stabilization for the one or more holographic optical elements. For this purpose, the temperature-regulating layer can be a heating film, such as, for example, an ITO heating film, a cooling film or a both heating and cooling film. Furthermore, the temperature-regulating layer can extend over the whole area along the first layer. The temperature-regulating layer can also extend only party along the first layer, for example only along sections of the first layer which comprise the one or more holographic optical elements.

A photosensitive material of the at least one first layer can have the property that it changes when there is a change in the temperature—that is to say a change in the ambient temperature or the operating temperature. By way of example, a macroscopic expansion or contraction can take place depending on temperature. This has the effect of giving rise to a shift in the maximum of the diffraction efficiency of the holographic optical element at different wavelengths (wavelength shift).

This wavelength shift can cause a reduced efficiency of the reconstruction of a corresponding hologram by the holographic optical element. This will be explained in more detail below.

The optical function of the holographic optical element is written into the photosensitive material using light in a predetermined wavelength range, during the production of the holographic optical element. This takes place at a specific temperature that is typically well-defined under laboratory conditions. If the temperature and/or the wavelength during operation deviate(s) from the corresponding conditions during production of the holographic optical element, the efficiency of the reconstruction of the hologram is reduced. This can be caused by a change in the structural spacing or the periodicity of an optical grating structure as a function of the temperature if the photopolymer expands or contracts. Such a reduction of the efficiency of the reconstructed hologram can be avoided or alleviated by the temperature stabilization.

Heat-conducting elements of the at least one second layer can comprise carbon tubes or carbon nanotubes and/or silver nanowires, for example.

Carbon tubes, in particular carbon nanotubes, are described e.g. in Dresselhaus, Mildred S., et al. “Carbon nanotubes.” The physics of fullerene-based and fullerene-related materials. Springer, Dordrecht, 2000. 331-379; and Popov, Valentin N. “Carbon nanotubes: properties and application.” Materials Science and Engineering: R: Reports 43.3 (2004): 61-102.

Silver nanowires are described e.g. in: Tsuji, Takeshi, Norihisa Watanabe, and Masaharu Tsuji. “Laser induced morphology change of silver colloids: formation of nano-size wires.” Applied surface science 211.1-4 (2003): 189-193.

Carbon nanotubes and/or silver nanowires can be advantageous particularly in the case of high optical requirements, since they cause little haze.

By way of example, heat-conducting elements of the at least one second layer could comprise metallic conductors.

By way of example, the heat-conducting elements can include heating elements, such as, for example, indium tin oxide (ITO), cooling elements or both heating and cooling elements. Heat-conducting elements implemented in this way can provide an implementation of the present disclosure that is particularly easy to fabricate.

Such heat-conducting elements can extend through the second layer in such a way that the second layer constitutes a whole-area or sectional temperature-regulating layer as described above.

It would be conceivable for the one or more heat-conducting elements of the at least one second layer to have a thermal conductivity that is not less than 1 W/meter per kelvin. By way of example, the one or more heat-conducting elements could have sheet resistances that are in the range of 5 to 50 ohms/sq. Preferably, the sheet resistance can be 20 ohms/sq.

If carbon tubes or silver nanowires are used, for example, then it is possible to flexibly adjust the sheet resistance by way of the variation of parameters in the corresponding production process. By way of example, a corresponding density of the nanostructures could be increased or decreased. It would be conceivable for the diameters of the corresponding nanostructures to be made larger or smaller. A variation of the orientation of the nanostructures in relation to a preferred orientation can be adjusted in terms of magnitude.

Efficient heating or cooling can be effected in this way, even in the case of comparatively thin second layers. Heat can be efficiently supplied or dissipated by the heat-conducting elements. If the at least one second layer is embodied as comparatively thin, an optical transparency can be ensured, and so an optical functionality is not restricted or is only slightly restricted.

For example, a diameter of silver nanowires could be producible in a controllable manner and be for example in a range of approximately 10 nm to a few 100 nm. A typical length of silver nanowires can be for example in the range of 10 to 100 μm.

The silver nanowires can form a network, that is to say provide a conductivity on a length scale which is significantly larger than the length of the silver nanowires themselves. The same applies, mutatis mutandis, to carbon nanotubes as well.

If the at least one second layer is embodied in each case as a film, then it is possible for the heat-conducting elements of the at least one second layer and/or electrodes as current supply/outgoing conductor to be embodied as a flexible or elastic circuit on the respective film.

By way of example, such a flexible electrical circuit could have a plurality of separately switchable regions. This could be implemented by means of a segmented arrangement of a plurality of dielectric layers or electrodes. Voltage could be supplied to the various dielectric layers via optically transparent conductor tracks as electrodes.

Active temperature stabilization and passive temperature stabilization can be implemented, depending on the implementation variant.

As a general rule, it would be conceivable for the heat-conducting element or the heat-conducting elements to be operated actively or passively.

In this regard, it would be conceivable, for example, for the system furthermore to have a heat sink. This heat sink could for example be arranged at least partly along the periphery of the at least one second layer and be thermally coupled to the heat-conducting elements of the at least one second layer.

This means, therefore, that it would be possible to implement a heat flow away from the holographic optical elements of the at least one first layer to the heat sink by means of the heat-conducting elements of the at least one second layer. Heat can thus be dissipated from the holographic optical elements, whereby particularly high temperature peaks are avoided and cooling can be provided. Electrodes for supplying and conducting away a heating current are not required in such an implementation variant. This enables a simple construction. The transparency of the corresponding layer stack can be adversely affected to a comparatively small extent because no electrodes are necessary.

By way of example, it would be conceivable for the heat sink to comprise a fluid channel. The fluid channel can be configured to guide a fluid.

By way of example, in one variant, it would be conceivable for ambient air to flow around the at least one second layer. It would also be conceivable for the fluid to be actively circulated in the fluid channel. By way of example, it would be conceivable for the system to comprise a pump. The latter can then be configured to circulate the fluid in the fluid channel.

The heat-conducting element of the at least one second layer can also be embodied as an active electrical heating element. That means that an applied electric current can be converted into heat by the heating element. Active temperature stabilization is made possible as a result.

By way of example, the system could have at least one pair of electrodes. The latter can be configured to establish an electrical contact between the electrical heating elements and a current source. The electrodes can thus serve for supplying current to the heat-conducting elements or conducting current away from the latter. By way of the resistance of the electrical heating elements, heat can then be generated in order to heat the at least one first layer. It would thus be possible for the electrodes to extend along the at least one second layer, at least along a partial section. A current flow perpendicular to the second layer can be made possible in this way. By way of example, a preferred direction of the heating elements—for example a direction along which, at least on average, carbon nanotubes or silver nanowires are oriented—could be arranged perpendicular to a plane of extent of the electrodes. Such a preferred direction can be achieved by corresponding symmetry breaking of one or more parameters during production (for example by an ordering magnetic field or a temperature gradient, etc.).

The electrodes can have an optical transmissivity of not less than 80% or not less than 90% in the visible spectrum.

By way of example, it would be conceivable for the system to comprise a plurality of pairs of electrodes which are separately switchable. This plurality of pairs of electrodes can be configured to establish in each case the electrical contact between the current source and different electrical heating elements of the electrical heating elements of the at least one second layer.

The separately switchable electrodes make it possible to attain locally different heating in the at least one first layer. By way of example, laterally—that is to say along the at least one first layer—offset regions of the at least one first layer could be heated to different extents depending on which pair(s) of the plurality of pairs of electrodes is or are “switched on” or “switched off”—i.e. subjected to current. Optical properties of the various holograms can be influenced in a targeted manner by means of such a local adjustment of the temperature. Moreover, it can sometimes happen that holograms are reconstructed locally; that means that only partial regions of the at least one first layer are in each case illuminated by a corresponding light source, for example in order to show different motifs; accordingly, temperature stabilization could be effected in each case only for the optically active partial regions.

In some examples, it would be conceivable for the system to be configured to implement intelligent control of the heating of the at least one layer, that is to say that active intelligent temperature stabilization can be made possible. By way of example, the system could comprise a temperature sensor and a current source and a controller. The controller can then be configured to adjust a current flow of the current source through the electrical heating elements (that is to say via the at least one pair of electrodes) on the basis of a temperature measurement value of the temperature sensor.

In other words, if the temperature measurement value indicates a lower temperature, for example, then a larger current flow can be used. By contrast, if the temperature measurement value indicates a lower temperature, a smaller current flow, down to zero, can be used. In this way, it is possible to achieve the temperature stabilization in relation to a target value. Active closed-loop control by means of a control loop can be implemented.

In this case, the controller can be configured in particular to adjust the current flow on the basis of a predefined target temperature.

In this case, the target temperature can be chosen such that the diffraction efficiency of the optical grating structure of the one or more holographic optical elements has a maximum at the target temperature for a predefined wavelength range of diffracted light. That means that a reconstruction of the hologram can be implemented particularly efficiently by use of the temperature stabilization. Little light is lost that is not used for reconstruction of the hologram.

The system can also have a light source. The light source can be configured to emit light in a predetermined wavelength range for the reconstruction of a hologram onto the holographic optical elements of the at least one first layer. That means that the target temperature can be chosen such that in the predetermined wavelength range—which is defined by the light source—the diffraction efficiency has the maximum.

A structural spacing of an optical grating structure of the one or more holographic optical elements, at the target temperature, can correspond to a wavelength of the light emitted by the light source. This is based on the insight that the polymer material which implements the optical grating structure can experience an expansion upon heating and can experience a contraction upon cooling; with the result that the structural spacing of the optical grating structure changes as a function of the temperature. A particularly efficient diffraction can be achieved for example if the structural spacing corresponds to the wavelength of the light. The target temperature can be chosen accordingly.

It is possible for the heat-conducting elements of the at least one second layer to have a thermal conductivity that varies laterally along the respective second layer. That means that the at least one second layer can have a high thermal conductivity in some sections or regions of the at least one second layer, while a comparatively low thermal conductivity is present in other sections or regions of the at least one second layer.

For example, such a laterally structured thermal conductivity could be attained by corresponding “in-plane” variation of production parameters of corresponding conducting elements, for example carbon nanotubes or silver nanowires. By way of example, it would be conceivable for a density of carbon nanotubes in or of silver nanowires to vary laterally, whereby the thermal conductivity can be structured laterally. The diameter of such structures could also be varied laterally, to give just two examples of possible microscopic parameters which enable a corresponding adjustment.

By way of example, such a lateral variation of the temperature stabilization could be achieved by different heat-conducting elements of the at least one second layer being arranged at different lateral regions of the at least one second layer. By way of example, different second layers could each have heat-conducting elements at different lateral regions in relation to the at least one first layer.

In the various examples described herein, optical clear adhesives can be used to attach the different layers to one another. As a result, a transparency of the corresponding structure can be ensured, which enables a variety of fields of application—for example head-up displays.

The holographic optical elements of the at least one first layer could generate one or more holograms using reflection geometry. That means, therefore, that the light from the light source impinges on the at least one first layer from one side; and the light is then also reflected onto this side, wherein the hologram can then be reconstructed in a volume region adjoining this side.

By way of example, it would be possible for the at least one substrate to comprise a first substrate for the at least one first layer, and also a second substrate for the at least one second layer. However, it would also be conceivable for the at least one substrate to comprise a common substrate for both the at least one first layer and the at least one second layer.

It would be conceivable for the at least one substrate to be fabricated from silicon or some other semiconductor material. By way of example, a semiconductor material could be used which has a band gap which is greater than the energy of photons in the visible spectrum, in order to enable an optical transparency in this way. The at least one substrate could alternatively or additionally be embodied as a film. By way of example, the at least one substrate could be fabricated in polymer-based fashion.

The at least one first layer could be fabricated from silicon or some other semiconductor material, for example. By way of example, a semiconductor material could be used which has a band gap which is greater than the energy of photons in the visible spectrum, in order to enable an optical transparency in this way. The at least one first layer can be produced in polymer-based fashion. The at least one first layer could comprise a photopolymer, for example. For example, the at least one first layer could comprise a plurality of first layers. Such a plurality of first layers can be embodied as a film stack. For example, the plurality of first layers could be produced in a roll-to-roll fabrication process.

The at least one second layer could be fabricated from silicon or some other semiconductor material, for example. By way of example, a semiconductor material could be used which has a band gap which is greater than the energy of photons in the visible spectrum, in order to enable an optical transparency in this way. The at least one second layer can be produced in polymer-based fashion.

Techniques connected with flexible/elastic circuits and/or printed circuits can be used in the case where films are used for the at least one second layer.

The at least one first layer could comprise a plurality of first layers in a corresponding layer stack. This layer stack of the plurality of first layers can be attached to the at least one second layer by means of an optical clear adhesive. As an alternative or in addition thereto, the at least one second layer can comprise a plurality of second layers in a corresponding layer stack and this layer stack can be attached to the at least one first layer by means of an optical clear adhesive.

A variety of application scenarios for a corresponding system are conceivable. By way of example, a corresponding system could be integrated into a mirror, for example a mirror for sales areas. Automotive application scenarios would also be conceivable. By way of example, a corresponding system could be used for a head-up display, which can be integrated for example in a windshield of a motor vehicle or some other window positioned in the driver's field of view. Put generally, the system can be integrated into an optical set-up. By way of example, a user would not necessarily need to look through the system (using “see-through geometry”), rather the temperature stabilization on the system leads to the manipulation of the entire optical set-up. A variety of techniques are conceivable for producing a system as described above. By way of example, in the case of film-based systems—that is to say with at least one of the at least one first layer and/or at least one of the at least one second layer being implemented as a film having elasticity—it would be conceivable to use a roll-to-roll fabrication process.

By way of example, the at least one first layer could be produced in a first roll-to-roll fabrication process and the at least one second layer could be produced in a second roll-to-roll fabrication process carried out separately from the first roll-to-roll fabrication process. That means, therefore, that the at least one first layer can be produced at a first point in time that can be different from a second point in time at which the at least one second layer is produced. Spatially separate production would be conceivable. In any case different fabrication processes can be used, that is to say that the movement of rolls in the first and second roll-to-roll fabrication processes can be controlled separately. After the end of the first roll-to-roll fabrication process and after the end of the second roll-to-roll fabrication process, the at least one first layer can then be connected to the at least one second layer, for example by means of an adhesive, in particular an optical clear adhesive.

The use of separate fabrication processes makes it possible to ensure particular flexibility and the production of the system, both logistically and regarding the variety of the possible implementation variants.

In a further example, it would be conceivable for the at least one first layer and the at least one second layer to be produced in a common roll-to-roll fabrication process. That means that the movement of the rolls for producing the at least one first layer and for producing the at least one second layer is controlled jointly. Such a strategy for production can enable a particularly short fabrication duration and efficient fabrication.

A method for temperature stabilization of one or more holographic optical elements is disclosed. In this case, the one or more holographic optical elements are embodied in at least one layer. An electrical heating element is arranged in a manner adjoining said at least one first layer, that is to say in thermal contact with the at least one first layer. The method comprises adjusting a current flow of a current source through the electrical heating element on the basis of a temperature measurement value of a temperature sensor arranged in a vicinity of the at least one layer.

Active temperature stabilization can be effected as a result. In particular, what can be achieved is that a high diffraction efficiency is attained at a target temperature during the reconstruction of a hologram by the one or more holographic optical elements.

The current flow can be adjusted on the basis of a target temperature, for example.

A diffraction efficiency of an optical grating structure of the one or more holographic optical elements can have a maximum at the target temperature for a predetermined wavelength range of light.

Said predetermined wavelength range can correspond to a wavelength range in which a light source emits light onto the one or more holographic optical elements in order to reconstruct a hologram in this way.

Sometimes such a light source can also have a dependence of the wavelength of the light on the temperature, that is to say that the light source can have a dependence of the emitted wavelength on the temperature (i.e. a temperature response).

In this case, it would be conceivable for corresponding regulation of active temperature stabilization also to take account of this temperature response of the light source.

By way of example, it would be conceivable for the method to comprise adjusting the target temperature on the basis of the temperature measurement value or a further temperature measurement value of a further temperature sensor, wherein the further temperature sensor is arranged in a vicinity of the light source that emits the light onto the one or more holographic optical elements. The target temperature can furthermore be adjusted on the basis of a predefined temperature response of the wavelength of the light. In this way, therefore, the target temperature can have a temperature dependence in order to compensate for the temperature response of the light source in this way.

The temperature response could for example be stored in a lookup table or be stored in parameterized fashion as a function.

The target temperature could alternatively or additionally be adjusted on the basis of a measurement value for an emission wavelength of the light emitted by the light source. In other words, for example, if a shift in the wavelength of the light emitted by the light source is observed by a corresponding spectrometer, then the target temperature could be correspondingly adjusted in order to attain a maximum diffraction efficiency in the corresponding wavelength range.

The features set out above and features that are described hereinbelow can be used not only in the corresponding combinations explicitly set out, but also in further combinations or in isolation, without departing from the scope of protection of the present invention.

### BRIEF DESCRIPTION OF THE DRAWINGS

FIG. 1 schematically illustrates a system comprising a plurality of layer stacks in accordance with various examples.

FIG. 2 schematically illustrates a plurality of electrodes for feeding laterally varying heating currents into heating elements.

FIG. 3 schematically illustrates a system comprising a plurality of layer stacks and also a temperature sensor, a controller and a current source in accordance with various examples.

FIG. 4 is a flowchart of one exemplary method.

FIG. 5 schematically illustrates the dependence of a diffraction efficiency of a holographic optical element on the temperature for a predetermined wavelength range in accordance with various examples.

FIG. 6 schematically illustrates a heat-conducting element and a temperature sink in accordance with various examples.

FIG. 7 is a flowchart of a method for producing a system in accordance with various examples.

### DETAILED DESCRIPTION OF THE INVENTION

The properties, features and advantages of this invention described above and the way in which they are achieved will become clearer and more clearly understood in association with the following description of the exemplary embodiments which are explained in greater detail in association with the drawings.

The present invention is explained in greater detail below on the basis of preferred embodiments with reference to the drawings. In the figures, identical reference signs denote identical or similar elements. The figures are schematic representations of various embodiments of the invention. Elements illustrated in the figures are not necessarily illustrated as true to scale. Rather, the various elements illustrated in the figures are rendered in such a way that their function and general purpose become comprehensible to a person skilled in the art. Connections and couplings between functional units and elements illustrated in the figures can also be implemented as an indirect connection or coupling. A connection or coupling can be implemented in a wired or wireless manner. Functional units can be implemented as hardware, software or a combination of hardware and software.

Techniques which make it possible to reconstruct holograms with high quality are described below. Corresponding optical systems are disclosed. The holograms are reconstructed by holographic optical elements. Holographic optical elements can be embodied as a volume structure or a surface structure. Holographic optical elements can be implemented by optical grating structures. The optical grating structures can be implemented by a local variation of the refractive index in a polymer material.

In accordance with various examples described herein, temperature stabilization of the temperature of one or more holographic optical elements is effected. This can be effected actively by heating. It would also be conceivable to enable the temperature stabilization by passively dissipating heat toward a heat sink. In any case heat-conducting elements are used which are arranged adjacent, that is to say thermally coupled, to one or more holographic optical elements. Said heat-conducting elements can be embodied for example as carbon tubes or silver nanowires.

FIG. 1 schematically illustrates a system 50. The system 50 has a first layer stack 70. The first layer stack 70 comprises a first substrate 71 and two layers 72, 73 (the latter may also be referred to as “first layers 72, 73”). The two layers 72, 73 each implement a holographic optical element 181 (illustrated in FIG. 1 in the upper inset for the layer 72; the grating structure obtained by the refractive index modulation is evident there).

The system 50 also has a second layer stack 80. The latter comprises a corresponding substrate 81 and two corresponding layers 82, 83 (the latter may also be referred to as “second layers 82, 83”), on which respectively electrodes 87, 88 are mounted.

The layers 72, 73, 82, 83 could be embodied in each case as films.

The layers 82, 83 each have heat-conducting elements 185, for example carbon nanotubes or silver nanowires (cf. lower inset in FIG. 1). These can form a network, such that the corresponding layer 82, 83 is heat-conducting or can also conduct electric current, between the electrodes 87, 88.

The heat-conducting elements 185 can carry current that is fed in from a current source via the electrodes 87, 88. The current then flows via the layer 82 between the electrodes 87, 88; the layer 83 serves for thermally linking the layer 82 to the layer stack 70. In this respect, the heat-conducting elements 185 in the example illustrated in FIG. 1 may also be referred to as heating elements. It generally holds true, however, that the electrodes 87, 88 are optional; the heat-conducting elements 185 could also be used for passive temperature stabilization by heat dissipation, without a current flow being necessary for heating.

The layer stack 70 is attached to the layer stack 80 by means of an optical clear adhesive 61. What is achieved in this way is that firstly a contact between the two layer stacks 70, 80 is established; and furthermore the optical transparency of the system 50 is influenced only slightly.

The electrodes 87, 88 are led along the layers 82, 83 outward toward the edge. The electrodes 87, 88 are preferably embodied so as to be thin—that is to say with a small dimension along the Z-direction—and almost optically transparent. The electrodes 87, 88 can be embodied for example as a flexible circuit on a film.

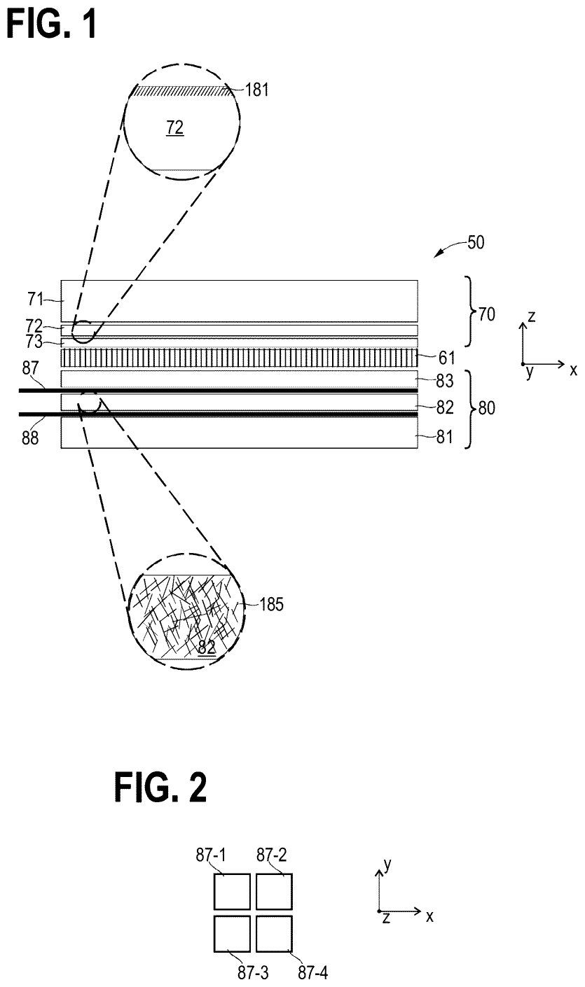

The electrodes 87, 88 extend in the X-Y-plane—that is to say laterally in relation to the various layers 71-73 and 81-83. It would be conceivable for the electrodes 87, 88 to be produced in a laterally segmented manner, that is to say that individual partial regions can be temperature-regulated in a differing manner in the X-Y-plane. A corresponding scenario is illustrated in FIG. 2, where different electrodes 87-1—87-4 are used in the X-Y-plane, which electrodes can be switched separately and thus address different heating elements. Counterelectrodes could be correspondingly laterally structured (these counterelectrodes are not illustrated).

The arrangement shown in FIG. 1 and FIG. 2 should be understood to be merely by way of example. Various modifications are conceivable. By way of example, it would be possible—as explained above—to provide passive temperature stabilization without electrodes 87, 88. By way of example, the following layer sequence would also be conceivable: (i) carrier substrate; (ii) first electrode; (iii) layer with heat-conducting elements; (iv) second electrode; (v) optical clear adhesive; (vi) one or more layers each forming a holographic optical element. In this case, only a single substrate is used, both for the layer with the heat-conducting elements and one or more layers with holographic optical elements (whereas two substrates are used for the HOE layer stack 70 and the temperature-stabilizing layer stack 80 in FIG. 1).

In a further modification, the arrangement shown in FIG. 1 and FIG. 2 can be supplemented by a temperature-regulating layer, which can be arranged in a manner adjoining the layers 72, 73. The temperature-regulating layer can be configured to provide temperature stabilization for the layers 72, 73. The temperature-regulating layer can provide the temperature stabilization in conjunction with or instead of the heat-conducting elements 185. For this purpose, the temperature-regulating layer can be arranged between layers 73 and 83 or instead of the layers 82, 83. The temperature-regulating layer can be a heating film, such as an ITO heating film, for example. The temperature-regulating layer can be a cooling film. The temperature-regulating layer can additionally be configured for temperature stabilization such that the temperature-regulating layer has both a cooling and a heating effect, depending on the present operating temperature of the layers 72, 73. The arrangement in FIG. 1 and FIG. 2 can also be supplemented by two temperature-regulating layers, wherein one of the two temperature-regulating layers is configured for temperature stabilization for heating and the other of the two temperature-regulating layers is configured for temperature stabilization for cooling.

Similarly to such variations concerning the embodiment and arrangement of the various layers, a variety of fabrication processes and production methods can also be used. By way of example, it would be possible in the example mentioned to produce the layers 1-5 jointly and to use them as a basis for lamination with the layer 6.

A further variation would concern the implementation of a thermal conductivity varying laterally in the X-Y-plane. By way of example, different types of heat-conducting elements can be embodied in different positions in the X-Y-plane in the layers 82, 83. A laterally varying thermal conductivity can be provided in this way.

By way of example, the optical system from FIG. 1 could be used for a head-up display. In this case, ambient light from surroundings of the vehicle can pass firstly through the layer stack 80 and subsequently through the layer stack 70 in order to reach an observer's eye in this way. Light from a light source can be specularly reflected into the corresponding optical path by being reflected by the holographic optical elements embodied by the layers 72, 73 (reflection geometry).

If the optical system in FIG. 1 is used as a head-up display, the optical system can be arranged in such a way that outlets of an air-conditioning system in the region of the dashboard are employed in such a way that outflowing cool air is additionally employed for temperature stabilization. This can improve the temperature stabilization in addition to the heat-conducting elements 185 and the temperature-regulating layer. It should be understood that the arrangement of the optical system in a vehicle can also be chosen at other locations such that outlets of the air-conditioning system are employed for temperature stabilization.

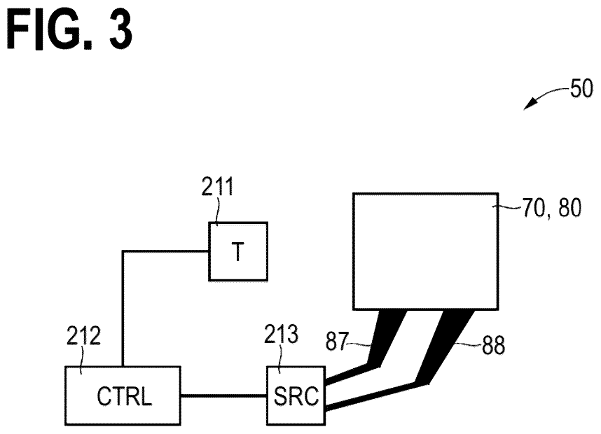

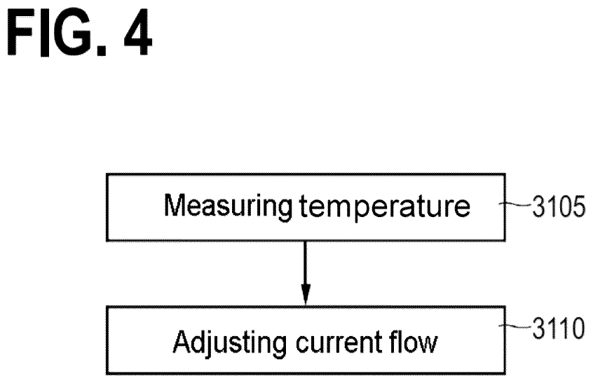

FIG. 3 illustrates aspects in relation to the system 50. In the example in FIG. 3, the system 50 comprises a temperature sensor 211, which is arranged in the thermal environment of the layer stack 70 and thus provides a temperature measurement value that is indicative of the temperature in the layers 72, 73 forming the holographic optical elements. A controller 212 is provided, which is configured to adjust a current flow of a current source 213 through the electrodes 87, 88—and thus through corresponding heating elements embodied by the heat-conducting elements in the respectively addressed layers 82, 83—on the basis of the temperature measurement value. The controller could be implemented for example by program code which is loaded from a memory and then executed by a processor. The controller could also be implemented as an application-specific integrated circuit. By way of example, the current flow can be adjusted on the basis of a predefined target temperature. Active temperature stabilization can be achieved in this way. A corresponding method for active temperature stabilization is also explained in association with FIG. 4.

FIG. 4 is a flowchart of one exemplary method for active temperature stabilization of one or more holographic optical elements. By way of example, holographic optical elements embodied in the layers 71, 72 of the layer stack 70 of the optical system 50 in accordance with FIG. 1 to FIG. 3 could be temperature-stabilized. However, other architectures of optical systems could also benefit from the techniques for active temperature stabilization disclosed in association with FIG. 4.

FIG. 4 can be executed by a controller, for example by a processor which loads program code from a memory and then executes it. By way of example, the method in FIG. 4 could be executed by the controller 212 from FIG. 3.

In box 3105, a temperature measurement value is obtained by a temperature sensor. This indicates an actual temperature of one or more holographic optical elements.

That is then followed, in box 3110, by adjusting a current flow of a current source through an electrical heating element arranged in a manner adjoining a corresponding layer embodying the one or more holographic optical elements. This is effected on the basis of the temperature measurement value from box 3105. By way of example, a target temperature can be taken into account.

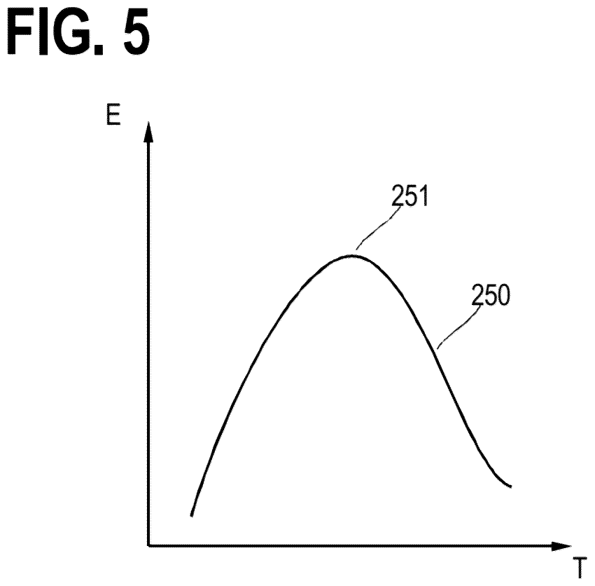

The diffraction efficiency attained by the one or more holographic optical elements can be maximized as a result. By way of example, FIG. 5 shows the dependence of the diffraction efficiency 250 on the temperature, for a specific wavelength range, for example that wavelength range in which a light source emits light for the reconstruction of the hologram by the one or more holographic optical elements. FIG. 5 shows that the diffraction efficiency 250 has a maximum 251 (for light of a specific wavelength or in a specific wavelength range); the target temperature can be chosen accordingly. There for example a structural spacing of a periodic structure embodying the holographic optical element (cf. FIG. 1) can correspond to the wavelength of the light.

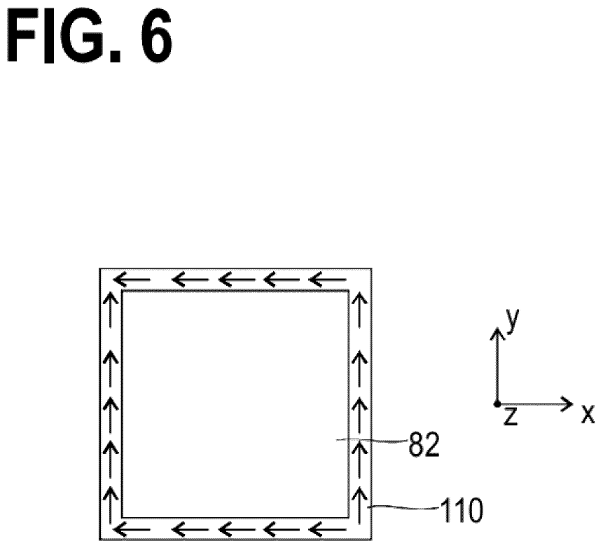

In this case, it is not necessary in all variants for active temperature stabilization to be effected, for example by a control loop that adjusts a heating current through heating elements on the basis of a deviation between an ACTUAL temperature and a target temperature, as described above. Techniques for passive temperature stabilization would also be conceivable. A corresponding example is illustrated in FIG. 6.

FIG. 6 schematically illustrates the layer 82 with heat-conducting elements 185 (not shown). It is evident there that a heat sink 110 surrounds the layer 82. That means that the heat-conducting elements 185 can dissipate heat toward a periphery of the layer 82 and thus toward the heat sink 110.

The heat sink could be embodied for example as a fluid channel configured to guide a fluid. The fluid could be circulated by a pump. In such a scenario with a heat sink, a temperature gradient develops toward the periphery of the heat-conducting element 382. In such a scenario in which no heating current is used, a link to an external current source via corresponding electrodes can be dispensable. That can be helpful in particular for integration into specific optical arrangements, for example in a motor vehicle windshield.

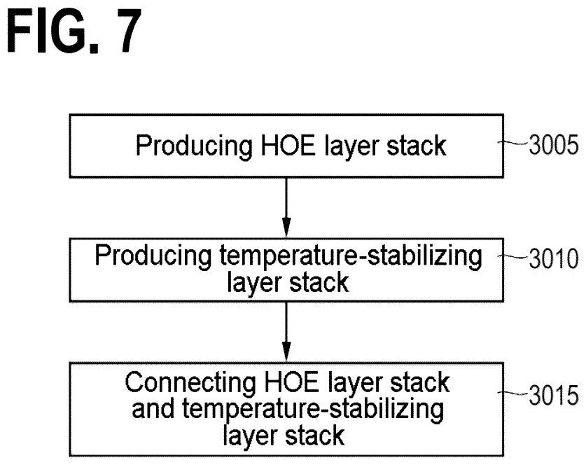

FIG. 7 is a flowchart of one exemplary production method for obtaining optical systems which include temperature-stabilized holographic optical elements.

Box 3005 involves producing an HOE layer stack comprising at least one first layer, wherein each of the at least one first layer embodies a corresponding holographic optical element. Box 3005 could be implemented in a corresponding roll-to-roll fabrication process.

Box 3010 involves producing a temperature-stabilizing layer stack comprising one or more layers including heat-conducting elements. The temperature-stabilizing layer stack could also have one or more pairs of electrons in order in this way to feed a heating current into the heat-conducting elements. Box 3010 could be implemented in a corresponding roll-to-roll fabrication process.

If box 3005 and box 3010 are implemented in separate fabrication processes, then box 3015 can subsequently involve connecting the corresponding layer stacks to one another—for example by means of an optical clear adhesive.

Sometimes it would be conceivable for box 3005 and box 3010 to be implemented jointly, i.e. in a common roll-to-roll fabrication process. In such a scenario, a connection in accordance with box 3015 can be effected automatically in the context of the common fabrication process.

By means of such techniques described herein, the temperature regulation of a holographic optical element can be made possible, that is to say that a fluctuation range of the temperature in the holographic optical element during typical operation can be reduced. The diffraction efficiency can be maximized as a result. That means that the light which is emitted by a light source and used for the reconstruction of a hologram contributes to a comparatively large proportion for the reconstruction of the hologram, or losses are minimized.

Such techniques can be helpful for example in particular in automotive applications, for instance head-up displays. This is owing to the fact that large ranges for the operating temperature—for example from minus 20° C. to plus 70° C.—are intended to be supported in automotive applications. That means that compared with a temperature that was present during the production of an optical grating structure of the holographic optical element—for example 25° C.—a fluctuation range of plus/minus 45 K may be present. In order to reduce a corresponding wavelength shift, it is possible to use the active or passive temperature stabilization, as disclosed above.

The following examples, in particular, have been described:

### EXAMPLE 1

System (50), comprising:
at least one substrate (71, 81),
at least one first layer (72, 73) applied on the at least one substrate (71, 81), wherein each of the at least one first layer (72, 73) comprises a respective holographic optical element, and
at least one second layer (82, 83) applied on the at least one substrate (71, 81), wherein each of the at least one second layer (82, 83) comprises at least one respective heat-conducting element (185).

### EXAMPLE 2

System (50) according to Example 1,
wherein the heat-conducting elements (185) of the at least one second layer (82, 83) comprise at least one out of carbon tubes or silver nanowires.

### EXAMPLE 3

System (50) according to Example 1 or 2,
wherein the heat-conducting elements (185) of the at least one second layer comprise metallic conductors, and/or wherein the heat-conducting element has a thermal conductivity of not less than 1 W/m/K.

### EXAMPLE 4

System (50) according to any of the preceding examples,
wherein each of the at least one second layer (82, 83) is embodied as a film,
wherein the heat-conducting elements of the at least one second layer (82, 83) and/or electrodes for electrically contacting the heat-conducting elements (185) are embodied as a flexible circuit on the respective film.

### EXAMPLE 5

System (50) according to any of the preceding examples, furthermore comprising:
a heat sink (110), which is arranged at least partly along the periphery of the at least one second layer (82) and which is thermally coupled to the heat-conducting elements of the at least one second layer (82).

### EXAMPLE 6

System (50) according to Example 5,
wherein the heat sink (110) comprises a fluid channel configured to guide a fluid.

### EXAMPLE 7

System (50) according to Example 6, wherein the system (50) furthermore comprises:
a pump configured to circulate the fluid in the fluid channel.

### EXAMPLE 8

System (50) according to any of the preceding examples,
wherein the heat-conducting elements of the at least one second layer are embodied as electrical heating elements.

### EXAMPLE 9

System (50) according to Example 8, furthermore comprising
at least one pair of electrodes (87, 87-1, 87-2, 87-3, 87-4, 88) configured to establish an electrical contact between the electrical heating elements of the at least one second layer (82, 83) and a current source (213).

### EXAMPLE 10

System (50) according to Example 9,
wherein the system (50) comprises a plurality of pairs of electrodes (87, 87-1, 87-2, 87-3, 87-4, 88) which are separately switchable,
wherein different pairs of the plurality of pairs of electrodes (87, 87-1, 87-2, 87-3, 87-4, 88) are configured to establish the electrical contact between the current source (213) and different electrical heating elements of the electrical heating elements of the at least one second layer (82, 83).

### EXAMPLE 11

System (50) according to Example 9 or 10,
wherein the electrodes of the at least one pair of electrodes (87, 87-1, 87-2, 87-3, 87-4, 88) extend along the at least one second layer.

### EXAMPLE 12

System (50) according to any of Examples 8 to 11, wherein the system (50) furthermore comprises:
a temperature sensor (211),
the current source (213), and
a controller (212) configured to adjust a current flow from the current source (213) through the electrical heating elements on the basis of a temperature measurement value of the temperature sensor (211).

### EXAMPLE 13

System (50) according to Example 12,
wherein the controller is configured to furthermore adjust the current flow on the basis of a predefined target temperature.

### EXAMPLE 14

System (50) according to Example 13,
wherein a diffraction efficiency of an optical grating structure of the one or more holographic optical elements has a maximum at the target temperature for a predetermined wavelength range of light.

### EXAMPLE 15

System (50) according to any of the preceding examples, wherein the system (50) furthermore comprises:
a light source configured to emit light in a predetermined wavelength range for the reconstruction of a hologram onto the holographic optical elements of the at least one first layer.

### EXAMPLE 16

System (50) according to Example 15, and according to Example 13 or 14,
wherein a structural spacing of an optical grating structure of the one or more holographic optical elements (181), at the target temperature, corresponds to a wavelength of the light.

### EXAMPLE 17

System (50) according to any of the preceding examples,
wherein the heat-conducting elements of the at least one second layer (82, 83) have a thermal conductivity that varies laterally along the respective second layer (82, 83).

### EXAMPLE 18

System (50) according to any of the preceding examples,
wherein different heat-conducting elements of the at least one second layer (82, 83) are arranged at different lateral regions of the at least one second layer (82, 83).

### EXAMPLE 19

System (50) according to any of the preceding examples,
wherein the at least one first layer is attached to the at least one second layer and/or the at least one substrate by means of an optical clear adhesive.

### EXAMPLE 20

System (50) according to any of the preceding examples,
wherein the holographic optical elements of the at least one first layer (72, 73) generate one or more holograms using reflection geometry.

### EXAMPLE 21

System (50) according to any of the preceding examples,
wherein the at least one substrate (71, 81) comprises a first substrate (71), on which the at least one first layer (72, 73) is applied,
wherein the at least one substrate (71, 81) comprises a second substrate (81), on which the at least one second layer (82, 83) is applied.

### EXAMPLE 22

System (50) according to any of the preceding examples,
wherein each of the at least one first layer (72, 73) is embodied as a film, and/or
wherein each of the at least one second layer (82, 83) is embodied as a film.

### EXAMPLE 23

System (50) according to any of the preceding examples,
wherein the at least one first layer (72, 73) comprises a plurality of first layers (72, 73) in a corresponding layer stack (70),
wherein the layer stack (70) of the plurality of first layers (72, 73) is attached to the at least one second layer by means of an optical clear adhesive (61).

### EXAMPLE 24

System (50) according to any of the preceding examples,
wherein the at least one second layer (82, 83) comprises a plurality of second layers (82, 83) in a corresponding layer stack (80),
wherein the layer stack (80) of the plurality of second layers (82, 83) is attached to the at least one first layer (82, 83) by means of an optical clear adhesive (61).

### EXAMPLE 25

Head-up display for a vehicle which comprises the system (50) according to any of Examples 1 to 24.

### EXAMPLE 26

Mirror which comprises the system (50) according to any of Examples 1 to 24.

### EXAMPLE 27

Method for producing the system (50) according to any of Examples 1 to 24, wherein the method comprises:
producing the at least one first layer (72, 73) in a first roll-to-roll fabrication process,
producing the at least one second layer (82, 83) in a second roll-to-roll fabrication process, which is carried out separately from the first roll-to-roll fabrication process, and
after the end of the first roll-to-roll fabrication process and after the end of the second roll-to-roll fabrication process, connecting the at least one first layer (72, 73) and the at least one second layer (82, 83) by means of an adhesive.

### EXAMPLE 28

Method for producing the system (50) according to any of Examples 1 to 24, wherein the method comprises:
producing the at least one first layer (72, 73) and the at least one second layer (82, 83) in a common roll-to-roll fabrication process.

### EXAMPLE 29

Method for temperature stabilization of one or more holographic optical elements, wherein the one or more holographic optical elements are embodied in at least one layer (72, 73), wherein an electrical heating element is arranged in a manner adjoining the at least one layer (72, 73), wherein the method comprises:
adjusting a current flow of a current source (213) through the electrical heating element on the basis of a temperature measurement value of a temperature sensor (211) arranged in a vicinity of the at least one layer (72, 73).

### EXAMPLE 30

Method according to Example 29,
wherein the current flow is furthermore adjusted on the basis of a target temperature.

### EXAMPLE 31

Method according to Example 30,
wherein a diffraction efficiency of an optical grating structure of the one or more holographic optical elements has a maximum at the target temperature for a predetermined wavelength range of light.

### EXAMPLE 32

Method according to Example 30 or 31, furthermore comprising:
adjusting the target temperature on the basis of the temperature measurement value or a further temperature measurement value of a further temperature sensor arranged in a vicinity of a light source that emits light onto the one or more holographic optical elements,
wherein the target temperature is furthermore adjusted on the basis of a predefined temperature response of a wavelength of the light.

### EXAMPLE 33

Method according to any of Examples 30 to 32, furthermore comprising:
adjusting the target temperature on the basis of a measurement value for an emission wavelength of light emitted by a light source that emits light onto the one or more holographic optical elements.

It goes without saying that the features of the embodiments and aspects of the invention described above can be combined with one another. In particular, the features can be used not only in the combinations described but also in other combinations or on their own, without departing from the scope of the invention.

1. A system, comprising:
at least one substrate,
at least one first layer applied on the at least one substrate, wherein each of the at least one first layer comprises a respective holographic optical element, and
at least one second layer applied on the at least one substrate, wherein each of the at least one second layer comprises at least one respective heat-conducting element.

2. The system as claimed in claim 1,
wherein the heat-conducting elements of the at least one second layer comprise at least one out of carbon tubes or silver nanowires.

3. The system as claimed in claim 1,
wherein the heat-conducting elements of the at least one second layer comprise metallic conductors, and/or wherein the heat-conducting element has a thermal conductivity of not less than 1 W/m/K.

4. The system as claimed in claim 1,
wherein each of the at least one second layer is embodied as a film,
wherein the heat-conducting elements of the at least one second layer and/or electrodes for electrically contacting the heat-conducting elements are embodied as a flexible circuit on the respective film.

5. The system as claimed in claim 1, furthermore comprising:
a heat sink, which is arranged at least partly along the periphery of the at least one second layer and which is thermally coupled to the heat-conducting elements of the at least one second layer.

6. The system as claimed in claim 1,
wherein the heat-conducting elements of the at least one second layer are embodied as electrical heating elements.

7. The system as claimed in claim 6, furthermore comprising
at least one pair of electrodes configured to establish an electrical contact between the electrical heating elements of the at least one second layer and a current source.

8. The system as claimed in claim 7,
wherein the system comprises a plurality of pairs of electrodes which are separately switchable,
wherein different pairs of the plurality of pairs of electrodes are configured to establish the electrical contact between the current source and different electrical heating elements of the electrical heating elements of the at least one second layer.

9. The system as claimed in claim 7, wherein the system furthermore comprises:
a temperature sensor,
the current source, and
a controller configured to adjust a current flow from the current source through the electrical heating elements on the basis of a temperature measurement value of the temperature sensor.

10. The system as claimed in claim 1, wherein the system furthermore comprises:
a light source configured to emit light in a predetermined wavelength range for the reconstruction of a hologram onto the holographic optical elements of the at least one first layer.

11. A method for producing the system as claimed in claim 1, wherein the method comprises:
producing the at least one first layer in a first roll-to-roll fabrication process,
producing the at least one second layer in a second roll-to-roll fabrication process, which is carried out separately from the first roll-to-roll fabrication process, and
after the end of the first roll-to-roll fabrication process and after the end of the second roll-to-roll fabrication process, connecting the at least one first layer and the at least one second layer by means of an adhesive.

12. A method for producing the system as claimed in claim 1, wherein the method comprises:
producing the at least one first layer and the at least one second layer in a common roll-to-roll fabrication process.

13. A method for temperature stabilization of one or more holographic optical elements, wherein the one or more holographic optical elements are embodied in at least one layer, wherein an electrical heating element is arranged in a manner adjoining the at least one layer,
wherein the method comprises:
adjusting a current flow of a current source through the electrical heating element on the basis of a temperature measurement value of a temperature sensor arranged in a vicinity of the at least one layer,
wherein the current flow is furthermore adjusted on the basis of a target temperature.

14. The method as claimed in claim 13, furthermore comprising:
adjusting the target temperature on the basis of the temperature measurement value or a further temperature measurement value of a further temperature sensor arranged in a vicinity of a light source that emits light onto the one or more holographic optical elements,
wherein the target temperature is furthermore adjusted on the basis of a predefined temperature response of a wavelength of the light.

15. The method as claimed in claim 13, furthermore comprising:
adjusting the target temperature on the basis of a measurement value for an emission wavelength of light emitted by a light source that emits light onto the one or more holographic optical elements.
